(19) United States
(12) Patent Application Publication
(10) Pub. No.: US 2022/0006260 A1
(43) Pub. Date: Jan. 6, 2022

(54) Self-Injection Locking Using Resonator On Silicon Based Chip

(71) Applicant: The Trustees of Columbia University in the City of New York, New York, NY (US)

(72) Inventors: Michal Lipson, New York, NY (US); Yair Antman, New York, NY (US); Xingchen Ji, New York, NY (US); Alexander L. Gaeta, New York, NY (US)

(21) Appl. No.: 17/476,632

(22) Filed: Sep. 16, 2021

Related U.S. Application Data
(63) Continuation of application No. PCT/US2020/023410, filed on Mar. 18, 2020.
(60) Provisional application No. 62/820,136, filed on Mar. 18, 2019.

(51) Int. Cl. H01S 5/065; H01S 5/068; H01S 5/026; H01S 5/06; H01S 5/20; H01S 5/10; H01S 5/14

(52) U.S. Cl. CPC H01S 5/0656; H01S 5/06821; H01S 5/026; H01S 2301/163; H01S 5/2036; H01S 5/1028; H01S 5/14; H01S 5/0612

(57) ABSTRACT

Disclosed are devices, methods, and systems for controlling output of a laser. An example device can comprise a first portion comprising a gain element and a second portion comprising a silicon material. The second portion can comprise a waveguide configured to receive light from the gain element, an optical resonator configured to at least partially reflect light back to the gain element via the waveguide, and a first tuning element configured to tune a resonant frequency of the optical resonator.

### CROSS-REFERENCE TO RELATED APPLICATIONS

This application is a continuation of International Application PCT/US2020/023410, filed Mar. 18, 2020, which claims the benefit of United States Patent Application No. 62/820,136 filed Mar. 18, 2019, each of which is hereby incorporated by reference in its entirety for any and all purposes.

### BACKGROUND

Self-injection locking is a widely used technique in which an external optical cavity is coupled to a laser by allowing back-reflections from the external cavity to propagate back into the laser cavity. The external cavity typically has a quality factor (Q factor) that is significantly higher than that of the laser cavity. When the resonant frequencies of the cavities are tuned to closely match one another, the feedback provided by the external cavity stabilizes the emission frequency of the laser and reduces its linewidth. This allows tuning of the lasing frequency and, in the case of multi-longitudinal mode lasers, reduce the number of lasing modes to one. There is, however, a long-felt need for on-chip integration of resonators and other components.

### SUMMARY

In meeting the described long-felt needs, disclosed are devices, methods, and systems for controlling output of a laser. An example device can comprise a first portion and a second portion. The first portion can comprise a gain element (e.g., a laser, laser cavity). The second portion can comprise a silicon material (e.g., a dielectric on silicon material, a dielectric material disposed on and/or adjacent the silicon material). The second portion can comprise a waveguide configured to receive light from the gain element, and an optical ring resonator (e.g., or other optical resonator) configured to at least partially reflect light back to the gain element via the waveguide. The second portion can comprise a first tuning element configured to tune a resonant frequency of the optical resonator. The first portion can comprise a first chip and the second portion can comprise a second chip. The first chip can be optically coupled (e.g., via alignment) with the second chip.

An example method can comprise outputting light from a gain element (e.g., a laser, laser cavity) disposed on a first portion to a waveguide disposed on a second portion. The second portion can comprise a silicon based material (e.g., a dielectric material can be disposed on the silicon and/or comprise one or more components of the second portion). The second portion can comprise the waveguide and an optical resonator (e.g., a partially reflecting optical resonator). The method can comprise tuning a resonant frequency of the optical resonator with a first tuning element, providing at least a portion of the light to a partially reflecting optical resonator, and reflecting at least a portion of the light received by the optical resonator to the gain element via the waveguide.

Additional advantages will be set forth in part in the description which follows or may be learned by practice. It is to be understood that both the foregoing general description and the following detailed description are exemplary and explanatory only and are not restrictive.

### BRIEF DESCRIPTION OF THE DRAWINGS

The accompanying drawings, which are incorporated in and constitute a part of this specification, illustrate embodiments and together with the description, serve to explain the principles of the methods and systems.

FIG. 1 shows a diagram of an example of self-injected laser cavity.

FIG. 2 is a diagram showing an example device for configured for injection-locking of a single spatial mode laser.

FIG. 3 is a diagram showing an example device configured for using multiple coherently combined lasers by mutual injection locking.

FIG. 4 is a diagram showing an example device configured for single spatial mode excitation of a multi-spatial-mode laser by mode-selective self-injection locking.

FIG. 5 is a diagram showing an example experimental setup for injection locking of a laser.

FIG. 6 is graph showing an example optical spectrum of the free-running laser.

FIG. 7 is a graph showing an example spectrum of an injection locked laser.

### DETAILED DESCRIPTION OF ILLUSTRATIVE EMBODIMENTS

Disclosed herein are methods, devices, and systems for using integrated silicon (Si) based platforms (e.g., such as silicon nitride (Si₃N₄)) for self-injection locking. Conventional approaches face challenges with the integration of high Q resonators on-chip. The use of integrated silicon based waveguides as disclosed herein allow for devices with low loss propagation on a small footprint, which enables production of high Q cavities in a mass-producible CMOS compatible process. The disclosed cavities can be coupled to external gain media via direct contact. The disclosed cavities coupled with the external gain media can be packaged together as one compact device.

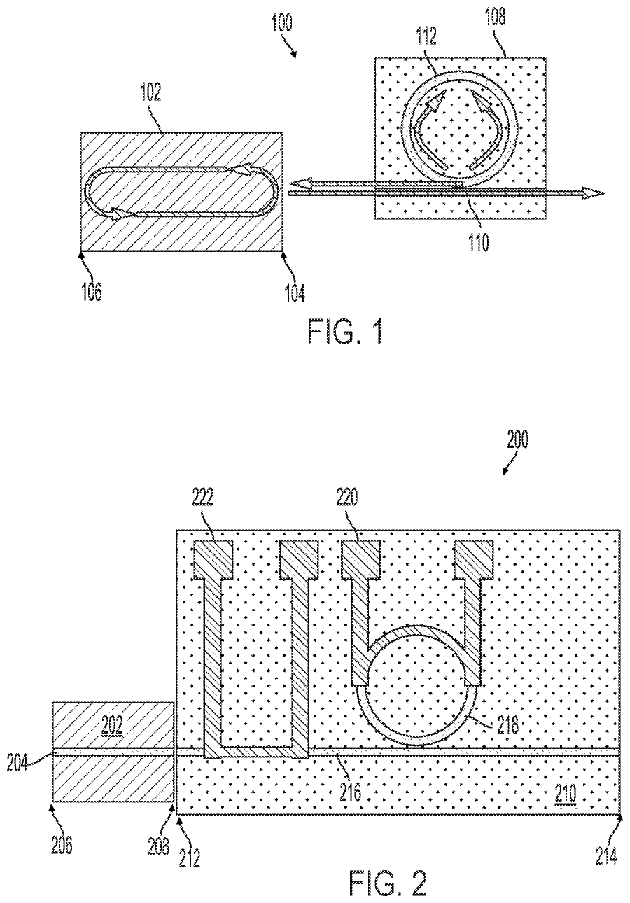

FIG. 1 shows a diagram of an example device 100. The device 100 can be configured as a self-injected laser cavity. The device 100 can comprise a laser cavity 102 (e.g., or gain medium, gain element). The laser cavity can comprise a Fabry-Perot laser. The laser cavity can comprise a front mirror 104. The laser cavity can comprise a back mirror 106. As shown by the arrows within the laser cavity 102, optical signals can be reflected between the front mirror 104 and the back mirror 106. The laser cavity 102 can be configured to reflect optical signals incident on the front mirror 104 that are not in resonance with the laser cavity 102. The laser cavity 102 can be configured to transmit optical signals incident on the front mirror 104 that are in resonance with the laser cavity 102.

The device 100 can comprise an external cavity 108 (e.g., a cavity external to the laser cavity 102). The external cavity 108 can comprise a silicon based material, such as silicon, silicon nitride, or a combination thereof. The external cavity 108 can comprise a first waveguide 110, only partially shown, located under the arrows shown. The external cavity 108 can comprise a second waveguide 112, such as an optical waveguide. The second waveguide 112 can be ring-shaped. The second waveguide 112 can be configured as an optical ring resonator.

The external cavity 108 can be optically coupled with the laser cavity 102. As shown by the arrows, optical signals can be received by the external cavity 108 from the laser cavity 102. The optical signals can be received by the first waveguide 110. The first waveguide 110 can be optically coupled to the second waveguide 112, such that at least a portion of the optical signals are transmitted to the second waveguide 112. The second waveguide 112 can reflect the at least the portion of the optical signals back to the laser cavity 102.

One important advantage of integrated Si based photonics is the ability to control the propagation of light on a miniature scale. Among others, Si based devices can include: splitters, combiners, phase shifters, feedback loops (e.g., cavities), reflectors, mode converters, a combination thereof, or other components. Such components can be configured for dynamic control over important elements of self-injection locking, such as absolute phase between gain elements and the external cavity, and the resonance frequencies of the cavities.

When considering the gain element, the reflectivity of the front mirror 104 of the laser cavity 102 is important. As described further herein, low reflectivity (e.g., such as in a Reflective Semi-Conductor Amplifier (RSOA)) relaxes the conditions under which effective injection locking takes place. On the other hand, higher reflectivity allows higher gain and higher saturation power. Disclosed herein are techniques for injection locking with a Fabry-Perot (FP) laser with a front mirror 104 have a medium-to-high quality factor (1). A silicon based external cavity can be configured to provide sufficient feedback to lock the FP laser, which allows for a laser that has high power while maintaining stable locking of a narrow linewidth lasing mode.

Described below are methods, systems, and devices for enabling linewidth narrowing while also leverage the high gain of FP lasers to enable ultra-high power, single mode, on-chip lasers. It should be understood that any feature of any example device disclosed can be combined with any feature of the other example devices described herein.

### Injection Locking of a Single Spatial Mode FP Laser

An example device can comprise a device implementing injection locking of a single spatial mode FP laser. FIG. 2 is a diagram showing an example device 200. The example device 200 can be configured to implement injection-locking of a single spatial mode FP laser. The device 200 can comprise a first portion 202. The first portion 202 can comprise a gain medium, gain element, a laser, a laser cavity, a combination thereof, and/or the like. The laser (e.g., or gain element, gain medium) can comprise a Fabry-Perot laser. A resonant frequency of the laser cavity of the laser can be adjusted by adjusting a laser pumping current.

The device 200 can comprise a first waveguide 204, such as an optical waveguide. The first waveguide 204 can be configured to carry optical signals between a first end 206 of the first portion 202 and a second end 208 of the first portion 202. The second end 208 can be opposite the first end 206. The first end 206 can comprise a mirror. The first end 206 can be transmissive, reflective, or a combination thereof. The second end 208 can comprise a mirror. The second end 208 can be transmissive, reflective, or a combination thereof. The second end 208 can be at least partially transmissive.

The device 200 can comprise a second portion 210. The second portion 210 can comprise an external cavity that is external to the laser cavity (e.g., or external to the first portion 202). The second portion 210 can comprise one or more of a chip, a photonic chip, an integrated circuit, a monolithically integrated portion, a combination thereof, and/or the like. A monolithically integrated portion (e.g., or chip, second portion 210) can comprise a circuit or group of circuits manufactured (e.g., via growth processes) on a single piece of material (e.g., semiconductor material, silicon, a wafer cut into individual portions). The monolithically integrated portion can comprise both electronic and optical components. The second portion 210 can comprise a semiconductor material, a silicon material (e.g., a material that comprises silicon), a combination thereof, and/or the like. The silicon material can comprise silicon nitride (Si₃N₄). The silicon material can comprise a dielectric layer disposed on a silicon layer. The dielectric layer can comprise silicon nitride. The second portion 210 can comprise a silicon substrate (e.g., or other silicon based layer). A dielectric material can be disposed on the silicon substrate. The dielectric material can form one or more waveguides (e.g., the second waveguide 216 and/or the third waveguide 218 described below). The dielectric material can comprise silicon nitride (Si₃N₄). The one or more waveguides can be disposed on the dielectric material.

The second portion 210 can be optically coupled to the first portion 202. The second portion 210 can comprise a third end 212 and a fourth end 214 opposite the third end 212. The third end 212 of the second portion 210 can be coupled to (e.g., aligned with, in contact with) the second end 208 of the first portion 202. The second portion 210 can comprise a second waveguide 216. The second waveguide can extend from the third end 212 to the fourth end 214. The second waveguide 216 can be configured to receive light from the first portion 202, the first waveguide 204, the laser, or a combination thereof. The second waveguide 216 can be optically coupled with (e.g., aligned with, in contact with) the first waveguide 204. The second waveguide 216 can be configured to output optical signals at the fourth end 214 of the second portion 210.

The second portion 210 can comprise a third waveguide 218. The third waveguide 218 can be ring-shaped. The third waveguide 218 can comprise an optical waveguide. The third waveguide 218 can comprise an optical ring resonator. The third waveguide 218 can be optically coupled with (e.g., located adjacent to) the second waveguide 216. The second waveguide 216 can optically couple the first portion 202 (e.g., the laser) and the third waveguide 218 (e.g., the optical ring resonator). The third waveguide 218 can be configured to at least partially reflect light back to the first portion 202 (e.g., the laser, laser cavity) via the second waveguide 216.

The second portion 210 can comprise a first tuning element 220 (e.g., phase tuning element, heating element). The first tuning element 220 can be coupled to the third waveguide 218 (e.g., the optical ring resonator). The first tuning element 220 can be configured to adjust a characteristic (e.g., phase, resonant frequency) of the third waveguide 218 by adjusting a heat (e.g., other property, voltage, current) applied to the third waveguide 218. The first tuning element 220 can be configured to tune a resonant frequency of the third waveguide 218 (e.g., the optical ring resonator). The first tuning element 220 can be disposed on (e.g., or adjacent to) at least a portion of third waveguide 218. The first tuning element 220 can be disposed on top of at least a portion of the third waveguide 218 (e.g., the ring resonator). The third waveguide 218 (e.g., optical ring resonator) can be tuned by the first tuning element 220 to cause one or more of: (1) output of a single longitudinal mode by the laser, (2) narrowing of a linewidth of a lasing mode of the laser, or (3) tuning a frequency of the laser. The third waveguide (e.g., optical ring resonator) can be tuned by the first tuning element 220 to cause one or more of injection locking, self-injection locking, or injection pulling of the laser.

The second portion 210 can comprise a second tuning element 222 (e.g., phase tuning element, heating element). The second tuning element 222 can be disposed adjacent a portion of the second waveguide 216. The second tuning element 222 can be disposed adjacent a portion of the second waveguide 216 between the laser and the third waveguide 218 (e.g., ring resonator). The second tuning element 222 can be configured to adjust a characteristic (e.g., phase, resonant frequency) of the second waveguide 216 by adjusting a heat (e.g., other property, voltage, current) applied to the second waveguide 216. The second tuning element 222 can be configured to adjust at least a phase of light passing between the laser and the third waveguide 218 (e.g., the optical ring resonator).

The third waveguide 218 can comprise a high quality factor (Q) resonator. A high Q can comprise a Q high enough such that the nonlinear oscillation threshold power (e.g., which is a function of Q) is lower than the power that the laser can supply. The Q can vary based on material, but, as an example, a high Q can comprise a Q greater than about 1 million (e.g., between about 1 million and about 2 million, between about 1 million and about 5 million, between about 1 million and about 10 million, between about 1 million and about 500 million, between about 1 million and about 100 million, between about 1 million and about 1 billion, between about 1 million and about 10 billion, between about 1 million and about 100 billion), a Q greater than about 100,000 (e.g., between about 100,000 and about 200,000, between about 100,000 and about 300,000, between about 100,000 and about 500,000, between about 100,000 and about 750,000, between about 100,000 and about 1 million), and/or the like.

Due to resonant Rayleigh scattering, some of the optical signals from the second portion 210 can be reflected back into the first portion 202 (e.g., the laser cavity), inducing self-injection locking. The phase the light accumulates in the path between the laser cavity and the third waveguide 218 (e.g., ring) can be adjusted with an integrated heater (e.g., the first tuning element 220, the second tuning element 222) deposited on top of the second portion 210 (e.g., on top of the chip) during the fabrication process. The resonant frequency of the third waveguide 218 (e.g., the ring resonator) can be tuned by the first tuning element 220. The resonant frequency of the first portion 202 (e.g., laser cavity) can be controlled by slightly adjusting the laser pumping current. By carefully tuning the tuning elements (e.g., the first tuning element 220, the second tuning element 222), optimal conditions for self-injection locking can be achieved, allowing one or more of selection of a single longitudinal mode, narrowing the linewidth of the lasing mode, tuning its frequency, or a combination thereof

### Multiple Coherently Combined FP Lasers by Mutual Injection Locking

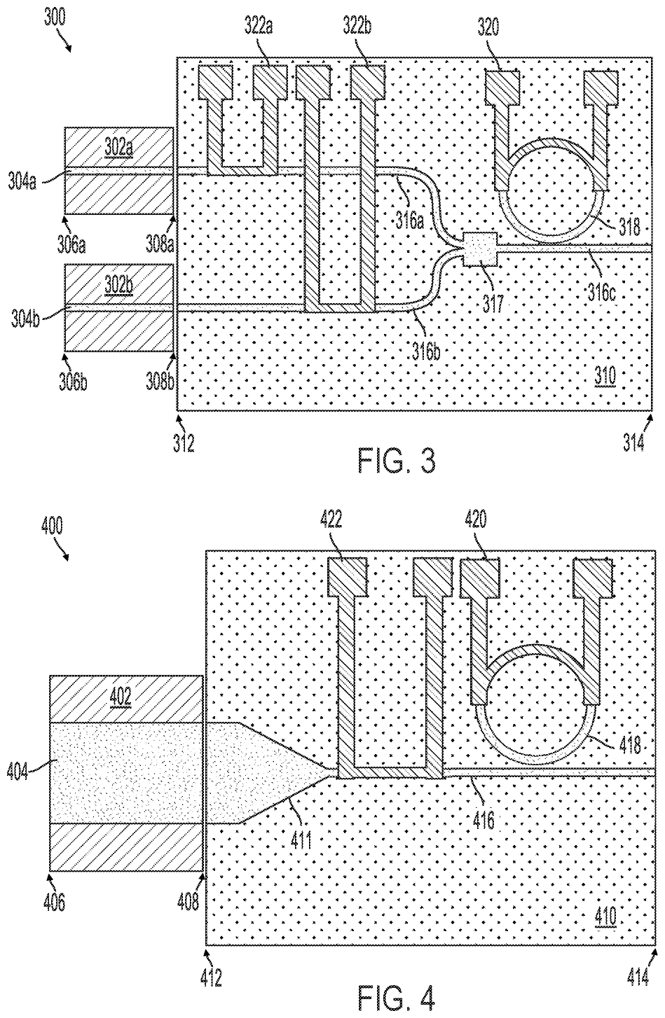

FIG. 3 is a diagram showing another example device 300. The example device 300 can be configured to implement multiple coherently combined lasers (e.g., FP lasers) by mutual injection locking.

The device 300 can comprise any of the features of the device 200 of FIG. 2 or the device 100 of FIG. 1. The device 300 can comprise at least two first portions 302a,b (e.g., at least two lasers, at least two laser cavities, at least two gain elements, at least two gain mediums). The at least two first portions 302a,b can comprise corresponding chips (e.g., integrated chip, photonic chip, at least two chips). The at least two first portions 302a,b can each comprise a corresponding first waveguide 304a,b, such as an optical waveguide.

The first waveguides 304a,b can be configured to carry optical signals between first ends 306a,b of the at least two first portions 302a,b and second end 308a,b of the at least two first portions 302a,b. The second ends 308a,b can be opposite the first ends 306a,b, respectively. The first ends 306a,b can be mirrors. The first ends 306a,b can be transmissive, reflective, or a combination thereof. The second ends 308a,b can be mirrors. The second ends 308a,b can be transmissive, reflective, or a combination thereof. The second ends 308a,b can be at least partially transmissive.

The device 300 can comprise a second portion 310. The second portion 310 can comprise a chip (e.g., integrated chip, photonic chip). The second portion 310 can comprise an external cavity that is external to the at least two first portions 302a,b (e.g., or external to the at least two laser cavities). The second portion 310 can comprise one or more of a chip, a photonic chip, an integrated circuit, a monolithically integrated portion, a combination thereof, and/or the like. The second portion 310 can comprise a semiconductor material, a silicon material (e.g., a material that comprises silicon), a combination thereof, and/or the like. The silicon material can comprise silicon nitride (Si₃N₄). The silicon material can comprise a dielectric layer disposed on a silicon layer. The dielectric layer can comprise silicon nitride. The second portion 310 can comprise a silicon substrate (e.g., or other silicon based layer). A dielectric material can be disposed on the silicon substrate. The dielectric material can form one or more waveguides (e.g., the plurality of second waveguides 316a,b,c and/or the third waveguide 318 described below). The dielectric material can comprise silicon nitride (Si₃N₄).

The second portion 310 can be optically coupled to the at least two first portions 302a,b. The second portion 310 can comprise a third end 312 and a fourth end 314 opposite the third end 312. The third end 312 of the second portion 310 can be coupled to (e.g., aligned with, in contact with) the second ends 308a,b of the at least two first portions 302a,b.

The second portion 310 can comprise a plurality of second waveguides 316a,b,c. A first path 316a and a second path 316b of the plurality of waveguides 316a,b,c can extend from the third end 312 of the second portion 310 to a combiner 317. The combiner 317 can be configured to combine the first path 316a and the second path 316b into a third path 316c of the plurality of waveguides 316a,b,c. The first path 316a can be optically coupled (e.g., aligned with) a first 302a of the at least two first portions 302a,b. The first path 316a can be optically coupled with the respective first waveguide 304a of the first 302a of the at least two first portions 302a,b. The second path 316b can be optically coupled (e.g., aligned) with a second 302b of the at least two first portions 302a,b. The second path 316b can be optically coupled with a respective first waveguide 304b of the second 302b of the at least two first portions 302a,b. The third path 316c of the plurality of second waveguides 316a,b,c can extend between the combiner 317 and the fourth end 314 of the second portion 310. The third path 316c of the plurality of second waveguides 316a,b,c can be configured to output optical signals at the fourth end 314 of the second portion 310.

The second portion 310 can comprise a third waveguide 318. The third waveguide 318 can be ring-shaped. The third waveguide 318 can comprise an optical waveguide. The third waveguide 318 can comprise an optical ring resonator. The third waveguide 318 can be optically coupled with (e.g., located adjacent to) one or more of the plurality of second waveguides 316a,b,c, such as the third path 316c. The plurality of second waveguides 316a,b,c can optically couple the at least two first portions 302a,b (e.g., the at least two lasers, the at least two laser cavities) and the third waveguide 318 (e.g., the optical ring resonator). The third waveguide 318 can be configured to at least partially reflect light back to one or more of the at least two first portions 302a,b (e.g., the at least two lasers, the at least two laser cavities) via the plurality of second waveguides 316a,b,c. The third waveguide 318 can comprise a high quality factor (Q) resonator, as described further herein.

The second portion 310 can comprise a first tuning element 320 (e.g., phase tuning element, heating element). The first tuning element 320 can be coupled to the third waveguide 318 (e.g., the optical ring resonator). The first tuning element 320 can be configured to adjust a characteristic (e.g., phase, resonant frequency) of the third waveguide 318 by adjusting a heat (e.g., other property, voltage, current) applied to the third waveguide 318. The first tuning element 320 can be configured to tune a resonant frequency of the third waveguide 318 (e.g., the optical ring resonator). The first tuning element 320 can be disposed on (e.g., or adjacent to) at least a portion of third waveguide 318. The first tuning element 320 can be disposed on top of at least a portion of the third waveguide 318 (e.g., the ring resonator). The third waveguide 318 (e.g., optical ring resonator) can be tuned by the first tuning element 320 to cause one or more of: (1) output of a single longitudinal mode by the at least two lasers, (2) narrowing of a linewidth of a lasing mode of the at least two lasers, or (3) tuning a frequency of the at least two lasers. The third waveguide 318 (e.g., optical ring resonator) can be tuned by the first tuning element 320 to cause one or more of injection locking, self-injection locking, or injection pulling of the at least two lasers.

The second portion 310 can comprise at least two second tuning elements 322a,b (e.g., at least two phase tuning elements, at least two heating element). The at least two second tuning elements 322a,b can be disposed adjacent corresponding paths of the plurality of second waveguides 316a,b,c. The at least two second tuning elements 322a,b can be disposed adjacent one or more paths of the plurality of second waveguides 316a,b,c between the at least two first portions 302a,b (e.g., the at least two lasers, laser cavities) and the third waveguide 318 (e.g., ring resonator). A first element 322a of the at least two second tuning elements 322a,b can be disposed adjacent (e.g., adjacent, or on top of, at least a portion of) the first path 316a of the plurality of second waveguides 316a,b,c. A second element 322b of the at least two second tuning elements 322a,b, can be disposed adjacent (e.g., adjacent, or on top of, at least a portion of) the second path 316b of the plurality of second waveguides 316a,b,c.

One or more of the at least two second tuning elements 322a,b can be configured to adjust a characteristic (e.g., phase, resonant frequency) of one or more of the first path 316a or the second path 316b by adjusting a heat (e.g., other property, voltage, current) applied to one or more of the first path 316a or the second path 316b. The one or more of the at least two second tuning elements 322a,b can be configured to adjust at least a phase of optical signals (e.g. light) passing between one or more of the at least two first portions 302a,b (e.g., the at least two lasers, laser cavities) and the third waveguide 318 (e.g., the optical ring resonator). The first element 322a can be configured to adjust a phase of optical signals on the first path 316a. The second element 322b can be configured to adjust a phase of optical signals on the second path 316b.

The second portion 310 can comprise a chip that includes a tuning element (e.g., phase tuning element, heater) for each first portion 302a,b (e.g., for each FP laser input). The combiner 317 can be configured to sums the radiation of the lasers and a high-Q ring (e.g., the third waveguide 318). By tuning the relative phases of the incoming lasers emission, the resonant frequency of the third waveguide 318 (e.g., the ring resonator) and the resonant frequency of each first portion 302a,b (e.g., FP cavity), the lasers can be made to injection lock one another through the feedback provided by the third waveguide 318 (e.g., the ring resonator). If mutual locking is achieved, all lasers can emit at the same frequency. If mutual locking is achieved, power can be coherently summed at the output of the third waveguide 318 (e.g., resulting in a low bandwidth, single spatial and longitudinal mode and high power beam).

### Single Spatial Mode Excitation of a Multi-Spatial-Mode FP Laser by Mode-Selective Self-Injection Locking

An example laser (e.g., FP laser) can lase at very high powers (e.g., greater than about 1 W) given sufficient pump current. In order to allow high currents and to prevent catastrophic damage to the output facet, such ultra-high power FP lasers can be made to be very wide, (e.g., exceeding about 100 um in width), which inevitably causes them to lase in a high number of spatial modes. While this allows very high power beams, the higher order modes diverge at high angles, reducing the brightness of the laser. The disclosed techniques can use injection locking to suppress all but one of the spatial mode. The disclosed techniques can focus the gain of the laser to a diffraction limited, high brightness and ultra-high power beam.

FIG. 4 is a diagram showing another example device 400. The example device 400 can be configured to implement single spatial mode excitation of a multi-spatial-mode FP laser by mode-selective self-injection locking.

The device 400 can comprise a first portion 402. The first portion 402 can comprise gain element, gain medium, a laser, a laser cavity, a combination thereof, and/or the like. The laser (e.g., or the gain element, gain medium) can comprise a Fabry-Perot laser. The laser (e.g., or the gain element, gain medium) can comprise a multi-spatial-mode laser. A resonant frequency of the laser cavity of the laser can be adjusted by adjusting a laser pumping current.

The device 400 can comprise a first waveguide 404, such as an optical waveguide. The first waveguide 404 can be configured to carry optical signals between a first end 406 of the first portion 402 and a second end 408 of the first portion 402. The second end 408 can be opposite the first end 406. The first end 406 can be transmissive, reflective, or a combination thereof The second end 408 can be transmissive, reflective, or a combination thereof. The second end 408 can be at least partially transmissive.

The device 400 can comprise a second portion 410. The second portion 410 can comprise an external cavity that is external to the laser cavity (e.g., or external to the first portion 402). The second portion 410 can comprise one or more of a chip, a photonic chip, an integrated circuit, a monolithically integrated portion, a combination thereof, and/or the like. The second portion 410 can comprise a semiconductor material, a silicon material (e.g., a material that comprises silicon), a combination thereof, and/or the like. The silicon material can comprise silicon nitride (Si₃N₄). The silicon material can comprise a dielectric layer disposed on a silicon layer. The dielectric layer can comprise silicon nitride. The second portion 410 can comprise a silicon substrate (e.g., or other silicon based layer). A dielectric material can be disposed on the silicon substrate. The dielectric material can form one or more waveguides (e.g., the second waveguide 416 and/or the third waveguide 418 described below). The dielectric material can comprise silicon nitride (Si₃N₄).

The second portion 410 can be optically coupled to the first portion 402. The second portion 410 can comprise a third end 412 and a fourth end 414 opposite the third end 412. The third end 412 of the second portion 410 can be coupled to (e.g., aligned with, in contact with) the second end 408 of the first portion 402.

The second portion 410 can comprise a mode converter 411. The mode converter 411 can comprise a spatial mode converter. The mode converter 411 can be configured to convert between a fundamental mode of a broad area input waveguide (e.g., the first waveguide) from the first portion 402 (e.g., from the laser) into a fundamental mode of a second waveguide 416. The second waveguide 416 can be comprised in the second portion 210. The optical ring resonator can be configured to reflect back light having the fundamental mode of the waveguide.

The second waveguide 416 can extend from the mode converter 411 to the fourth end 414. The second waveguide 416 can be configured to receive (e.g., via the mode converter 411) light from the first portion 402, the first waveguide 404, the laser, or a combination thereof. The second waveguide 416 can be optically coupled with (e.g., aligned with, in contact with) the first waveguide 404 (e.g., via the mode converter 411). The second waveguide 416 can be configured to output optical signals at the fourth end 414 of the second portion 410.

The second portion 410 can comprise a third waveguide 418. The third waveguide 418 can be ring-shaped. The third waveguide 418 can comprise an optical waveguide. The third waveguide 418 can comprise an optical ring resonator. The third waveguide 418 can be optically coupled with (e.g., located adjacent to) the second waveguide 416. The second waveguide 416 (e.g., and the mode converter 411) can optically couple the first portion 402 (e.g., the laser) and the third waveguide 418 (e.g., the optical ring resonator). The third waveguide 418 can be configured to at least partially reflect light back to the first portion 402 (e.g., the laser, laser cavity) via the second waveguide 416.

The second portion 410 can comprise a first tuning element 420 (e.g., phase tuning element, heating element). The first tuning element 420 can be coupled to the third waveguide 418 (e.g., the optical ring resonator). The first tuning element 420 can be configured to adjust a characteristic (e.g., phase, resonant frequency) of the third waveguide 418 by adjusting a heat (e.g., other property, voltage, current) applied to the third waveguide 418. The first tuning element 420 can be configured to tune a resonant frequency of the third waveguide 418 (e.g., the optical ring resonator). The first tuning element 420 can be disposed on (e.g., or adjacent to) at least a portion of third waveguide 418. The first tuning element 420 can be disposed on top of at least a portion of the third waveguide 418 (e.g., the ring resonator). The third waveguide 418 (e.g., optical ring resonator) can be tuned by the first tuning element 420 to cause one or more of: (1) output of a single longitudinal mode by the laser, (2) narrowing of a linewidth of a lasing mode of the laser, or (3) tuning a frequency of the laser. The third waveguide 418 (e.g., optical ring resonator) can be tuned by the first tuning element 220 to cause one or more of injection locking, self-injection locking, or injection pulling of the laser. The third waveguide 418 can be configured (e.g., designed, or configured via the first tuning element 420) to reflect back optical signals having the fundamental mode of the second waveguide 416.

The second portion 410 can comprise a second tuning element 422. The second tuning element 422 can be disposed adjacent a portion of the second waveguide 416. The second tuning element 422 can be disposed adjacent a portion of the second waveguide 416 between the laser and the third waveguide 418 (e.g., ring resonator). The second tuning element 422 can be configured to adjust a characteristic (e.g., phase, resonant frequency) of the second waveguide 416 by adjusting a heat (e.g., other property, voltage, current) applied to the second waveguide 416. The second tuning element 422 can be configured to adjust at least a phase of light passing between the laser and the third waveguide 418 (e.g., the optical ring resonator). The third waveguide 418 can comprise a high quality factor (Q) resonator, as described further herein.

The first waveguide 404 can be designed to be broad enough to accommodate high order modes. Light from transmitted via the second end 408 can be fed into the mode converter 411 (e.g., a spatial mode converter) that converts the fundamental mode of the broad area input waveguide into the fundamental mode of the second waveguide 416 (e.g., a bus waveguide). The third waveguide 418 (e.g., the ring resonator) can be designed to support only the fundamental spatial mode which gets reflected back to the mode converter 411. The fundamental mode of second waveguide 416 can be converted back to the fundamental broad-area input waveguide mode, causing selective injection locking of just the first order spatial mode (e.g., of the FP laser), thereby only one spatial and one longitudinal modes are allowed to lase.

Note that when coupling a FP laser to a Si based chip, a broad size mode can be very advantageous for at least two reasons. Coupling a high power beam into a small area mode includes focusing to a tight spot on the facet of the chip, which can result in damage. Here, the power is spread over a broad area at the input of the chip, reducing the risk of damage. Efficient coupling includes accurate alignment of the chips in order to overlap the mode profiles. The accuracy of the alignment is directly proportional to the size of the mode and in most cases should be a fraction of the mode size, hence a large mode size could significantly simplify the alignment procedure.

Additional information, aspects, and examples are provided as follows.

### Injection Locking Properties

### Energy Collapse to a Single Longitudinal Mode

With ideal phase alignment and resonant frequency matching between the laser and external cavities, it was shown that complete energy collapse in which a single mode dominates happens under relatively modest coupling ratio between the cavities, Γ²˜10⁻⁴. Here Γ² is the ratio of the power entering the external cavity and power returning back to the laser cavity.

### Frequency Pulling

Once locking is achieved, the frequency of the external cavity can be tuned within a range Δf_{lock} and maintain locking:

$$Δ {f}_{lock} = \sqrt{1 + {a}_{g}^{2}} \frac{Γ}{{Q}_{a}} {v}_{0}$$

Here, α_{g} is the laser phase-amplitude coupling factor, vₒ is the optical carrier frequency and Q_{d} is the Q factor of the Fabry-Perot cavity. With typical values of α_{g}=4, Q_{d}=10⁴, Γ=0.1 and vₒ=200 THz, we have Δf_{lock}=8 GHz. This means that if the cavity resonance is tuned within a span 8 GHz, the lasing frequency is expected to follow it closely, thus allowing fine frequency tuning via voltage application to the Si based chip.

### Linewidth Narrowing

The linewidth of the injection locked mode is expected to be lower than the free-running unlocked mode by the following factor:

$$\frac{δ {v}_{locked}}{δ {v}_{f r e e}} = \frac{{Q}_{d}^{2} 1}{{Q}_{m}^{2} 16 {Γ}^{2} ( 1 + {a}_{g}^{2} )}$$

where Qₘ is the Q factor of the external cavity. With Qₘ=5×10⁶ and δv_{free}=10 MHz, we have δv_{locked}=1.4 Hz.

### Preliminary Results

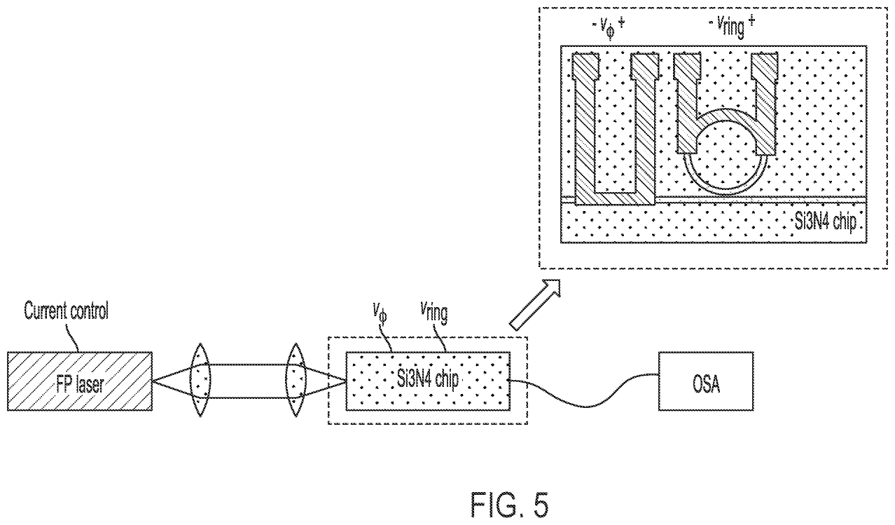

FIG. 5 is a diagram showing an example experimental setup for injection locking of a FP laser. Injection locking by a Si based external cavity was demonstrated experimentally, as shown in FIG. 5. A FP laser was coupled into a Si₃N₄ chip by collimating the laser's output beam with a lens. The collimated output beam was focused to roughly the size of the mode of the Si₃N₄ bus waveguide with a second lens. The laser driving current was stabilized while the voltages applied to heaters on the Si₃N₄ chip are tuned to achieve injection locking. The optical spectrum is measured with an Optical Spectrum Analyzer (OSA).

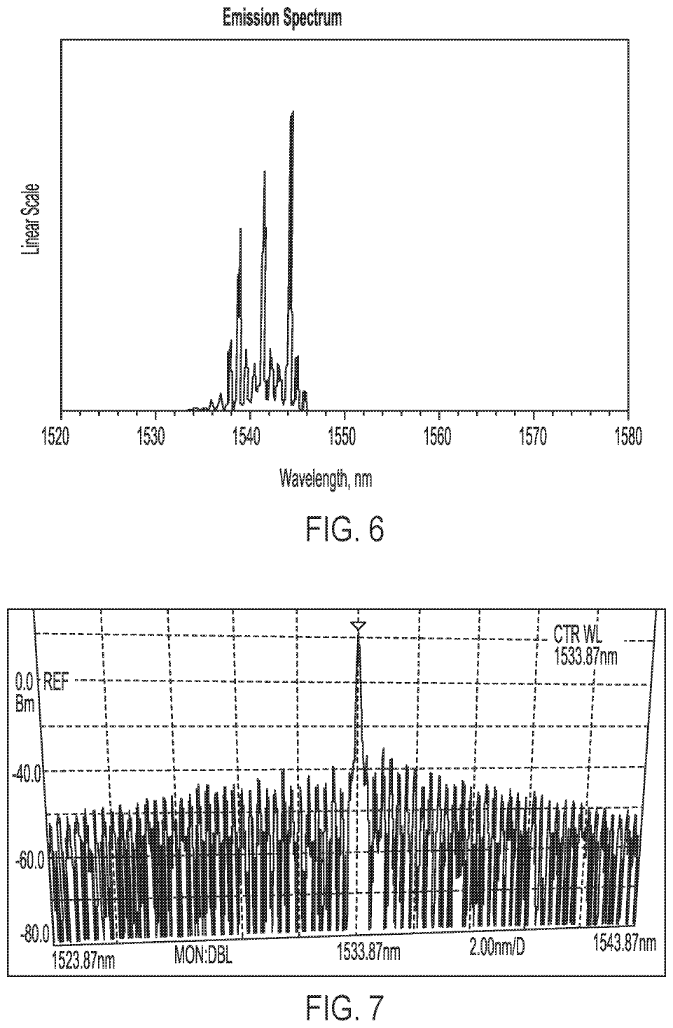

FIG. 6 is graph showing an example optical spectrum of the free-running FP laser. The free running spectrum of the FP laser (taken from the manufacturer data sheet) is shown in FIG. 6, featuring a very wide spectrum, several nanometers wide, and multiple lasing modes. When one of the modes is injection locked, the effect of “energy collapse” takes place and a single frequency emerges, as shown in the measured spectrum given in FIG. 7. FIG. 7 is a graph showing an example spectrum of an injection locked FP laser.

The measured side lobe suppression ratio is more than 30 dB. The laser output power is 3 mW, and the measured power at the output of the chip is 316 uW. The power of the single lasing frequency is 150 uW, which suggests slightly less than 50% conversion efficiency.

The present disclosure is directed to at least the following aspects.

Aspect 1. A device, comprising, consisting of, or consisting essentially of: a first portion comprising a gain element; and a second portion comprising a silicon material (e.g., a dielectric material disposed on silicon), wherein the second portion comprises (e.g., or consists or consists essentially of): a waveguide configured to receive light from the gain element; an optical resonator (e.g., an integrated optical resonator) configured to at least partially reflect light back to the gain element via the waveguide; and a first tuning element (e.g., first phase tuning element, first heating element) configured to tune a resonant frequency of the optical ring resonator. The first tuning element can be coupled to the optical resonator. The dielectric material can comprise the waveguide and/or the optical resonator.

Aspect 2. The device of aspect 1, wherein the optical resonator is tuned by the first tuning element to cause one or more of: (1) output of a single longitudinal mode by the gain element (e.g., the laser), (2) output of a single transversal mode by gain element (e.g., the laser), (3) narrowing of a linewidth of a lasing mode of the gain element (e.g., the laser), or (4) tuning a frequency of the gain element (e.g., the laser).

Aspect 3. The device of any one of aspects 1-2, wherein the optical resonator comprises a ring resonator. The optical resonator can be tuned by the first heating element to cause one or more of injection locking, self-injection locking, or injection pulling of the laser.

Aspect 4. The device of any one of aspects 1-3, wherein the gain element comprises one or more of a Fabry-Perot laser, a multimodal laser, or a multimodal Fabry-Perot laser.

Aspect 5. The device of any one of aspects 1-4, wherein the silicon material comprises silicon nitride. Additionally or alternatively, a dielectric material can be disposed on (e.g., directly in contact with, disposed adjacent with one or more intervening layers between) the silicon material. The dielectric material can comprise silicon nitride. The dielectric material can comprise one or more of the waveguide or the optical resonator.

Aspect 6. The device of any one of aspects 1-5, wherein the second portion comprises one or more of a chip, an integrated circuit, or a monolithically integrated portion.

Aspect 7. The device of any one of aspects 1-6, wherein the first tuning element is disposed on at least a portion of the optical resonator, the first tuning element optionally being disposed on top of at least a portion of the optical resonator.

Aspect 8. The device of any one of aspects 1-7, further comprising a second tuning element (e.g., a second phase tuning element, a second heating element) disposed adjacent a portion of the waveguide between the gain element and the optical resonator, wherein the second tuning element is configured to adjust at least a phase of light passing between the gain element and the optical resonator.

Aspect 9. The device of any one of aspects 1-8, wherein a resonant frequency of gain element (e.g., a laser cavity of a laser) is adjusted by a laser pumping current (e.g., instead of the first tuning element). In some aspects, the first tuning element can be omitted from the device. Instead of using the first tuning element, the laser pumping current can be adjusted.

Aspect 10. The device of any one of aspects 1-9, wherein the waveguide is optically coupled to the gain element (e.g., laser) and the optical resonator.

Aspect 11. The device of any one of aspects 1-10, further comprising an additional gain element (e.g., additional laser), wherein the waveguide comprises: a first path optically coupled to the gain element; a second path optically coupled to the additional gain element; and a combiner configured to combine the first path and the second path into a third path, wherein the optical resonator reflects light back to one or more of the gain element or the additional gain element via the third path.

Aspect 12. The device of aspect 11, wherein the additional gain element is disposed on the first portion.

Aspect 13. The device of any of aspects 11-12, further comprising a third tuning element (e.g., third phase tuning element, third heating element) disposed adjacent a portion of the second path of the waveguide between the gain element and the optical resonator, wherein the third tuning element is configured to adjust at least a phase of light passing between the additional gain element and the optical resonator.

Aspect 14. The device of any one of aspects 1-13, wherein the gain element comprises a multi-spatial-mode laser (e.g., a multimodal laser, a multimodal gain element, a multimodal laser cavity), and wherein the device further comprises a spatial mode converter configured to convert between a fundamental mode of a broad area input waveguide from the gain element into a fundamental mode of the waveguide, wherein the optical resonator is configured to reflect back light having the fundamental mode of the waveguide.

Aspect 15. The device of aspect 14, wherein the spatial mode converter is disposed on the second portion.

Aspect 16. The device of any one of aspects 1-15, wherein the first portion (e.g., gain element) comprises a laser cavity and the second portion comprises an external cavity.

Aspect 17. A method (e.g., of operating the device of any of claims 1-16), comprising, consisting of, or consisting essentially of: outputting light from a gain element (e.g., laser) disposed on a first portion to a waveguide disposed on a second portion, wherein the second portion comprises a silicon-based material, and wherein the second portion comprises the waveguide (e.g., the waveguide comprise a dielectric material disposed on the silcon-based material) and a partially reflecting optical resonator; tuning a resonant frequency of the optical resonator (e.g., by applying heat) with a first tuning element (e.g., a phase tuning element, a heating element, a resistive heating element); providing at least a portion of the light to a partially reflecting optical resonator; and reflecting at least a portion of the light received by the optical resonator to the gain element (e.g., laser) via the waveguide.

Aspect 18. The method of aspect 17, wherein the optical resonator is tuned by the first tuning element to cause one or more of: (1) output of a single longitudinal mode by the gain element (e.g., laser), (2) output of a single transversal mode by gain element (e.g., the laser), (3) narrowing of a linewidth of a lasing mode of the gain element (e.g., laser), or (4) tuning a frequency of the gain element (e.g., laser).

Aspect 19. The method of any one of aspects 17-18, wherein the optical resonator is tuned by the first tuning element to cause one or more of injection locking, self-injection locking, or injection pulling of the laser.

Aspect 20. The method of any one of aspects 17-19, wherein second portion comprises one or more of a chip, an integrated circuit, or a monolithically integrated portion.

It is to be understood that the methods and systems are not limited to specific methods, specific components, or to particular implementations. It is also to be understood that the terminology used herein is for the purpose of describing particular embodiments only and is not intended to be limiting.

As used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other components, integers or steps. “Exemplary” means “an example of” and is not intended to convey an indication of a preferred or ideal embodiment. “Such as” is not used in a restrictive sense, but for explanatory purposes.

Components are described that can be used to perform the described methods and systems. When combinations, subsets, interactions, groups, etc., of these components are described, it is understood that while specific references to each of the various individual and collective combinations and permutations of these may not be explicitly described, each is specifically contemplated and described herein, for all methods and systems. This applies to all aspects of this application including, but not limited to, operations in described methods. Thus, if there are a variety of additional operations that can be performed it is understood that each of these additional operations can be performed with any specific embodiment or combination of embodiments of the described methods.

As will be appreciated by one skilled in the art, the methods and systems can take the form of an entirely hardware embodiment, an entirely software embodiment, or an embodiment combining software and hardware aspects. Furthermore, the methods and systems can take the form of a computer program product on a computer-readable storage medium having computer-readable program instructions (e.g., computer software) embodied in the storage medium. More particularly, the present methods and systems can take the form of web-implemented computer software. Any suitable computer-readable storage medium can be utilized including hard disks, CD-ROMs, optical storage devices, or magnetic storage devices.

Embodiments of the methods and systems are described herein with reference to block diagrams and flowchart illustrations of methods, systems, apparatuses and computer program products. It will be understood that each block of the block diagrams and flowchart illustrations, and combinations of blocks in the block diagrams and flowchart illustrations, respectively, can be implemented by computer program instructions. These computer program instructions can be loaded on a general-purpose computer, special-purpose computer, or other programmable data processing apparatus to produce a machine, such that the instructions which execute on the computer or other programmable data processing apparatus create a means for implementing the functions specified in the flowchart block or blocks.

These computer program instructions can also be stored in a computer-readable memory that can direct a computer or other programmable data processing apparatus to function in a particular manner, such that the instructions stored in the computer-readable memory produce an article of manufacture including computer-readable instructions for implementing the function specified in the flowchart block or blocks. The computer program instructions can also be loaded onto a computer or other programmable data processing apparatus to cause a series of operational steps to be performed on the computer or other programmable apparatus to produce a computer-implemented process such that the instructions that execute on the computer or other programmable apparatus provide steps for implementing the functions specified in the flowchart block or blocks.

The various features and processes described above can be used independently of one another, or can be combined in various ways. All possible combinations and sub-combinations are intended to fall within the scope of this disclosure. In addition, certain methods or process blocks can be omitted in some implementations. The methods and processes described herein are also not limited to any particular sequence, and the blocks or states relating thereto can be performed in other sequences that are appropriate. For example, described blocks or states can be performed in an order other than that specifically described, or multiple blocks or states can be combined in a single block or state. The example blocks or states can be performed in serial, in parallel, or in some other manner. Blocks or states can be added to or removed from the described example embodiments. The example systems and components described herein can be configured differently than described. For example, elements can be added to, removed from, or rearranged compared to the described example embodiments.

It will also be appreciated that various items are illustrated as being stored in memory or on storage while being used, and that these items or portions thereof can be transferred between memory and other storage devices for purposes of memory management and data integrity. Alternatively, in other embodiments, some or all of the software modules and/or systems can execute in memory on another device and communicate with the illustrated computing systems via inter-computer communication. Furthermore, in some embodiments, some or all of the systems and/or modules can be implemented or provided in other ways, such as at least partially in firmware and/or hardware, including, but not limited to, one or more application-specific integrated circuits (“ASICs”), standard integrated circuits, controllers (e.g., by executing appropriate instructions, and including microcontrollers and/or embedded controllers), field-programmable gate arrays (“FPGAs”), complex programmable logic devices (“CPLDs”), etc. Some or all of the modules, systems, and data structures can also be stored (e.g., as software instructions or structured data) on a computer-readable medium, such as a hard disk, a memory, a network, or a portable media article to be read by an appropriate device or via an appropriate connection. The systems, modules, and data structures can also be transmitted as generated data signals (e.g., as part of a carrier wave or other analog or digital propagated signal) on a variety of computer-readable transmission media, including wireless-based and wired/cable-based media, and can take a variety of forms (e.g., as part of a single or multiplexed analog signal, or as multiple discrete digital packets or frames). Such computer program products can also take other forms in other embodiments. Accordingly, the disclosed technology can be practiced with other computer system configurations.

While the methods and systems have been described in connection with preferred embodiments and specific examples, it is not intended that the scope be limited to the particular embodiments set forth, as the embodiments herein are intended in all respects to be illustrative rather than restrictive.

It will be apparent to those skilled in the art that various modifications and variations can be made without departing from the scope or spirit of the present disclosure. Other embodiments will be apparent to those skilled in the art from consideration of the specification and practices described herein. It is intended that the specification and example figures be considered as exemplary only, with a true scope and spirit being indicated by the following claims.

What is claimed:

1. A device, comprising:
a first portion comprising a gain element; and
a second portion comprising a silicon material, wherein the second portion comprises:
a waveguide configured to receive light from the gain element;
an optical resonator configured to at least partially reflect light back to the gain element via the waveguide; and
a first tuning element configured to tune a resonant frequency of the optical resonator.

2. The device of claim 1, wherein the optical resonator is tuned by the first tuning element to cause one or more of: (1) output of a single longitudinal mode by the gain element, (2) output of a single transversal mode by the gain element, (3) narrowing of a linewidth of a lasing mode of the gain element, or (4) tuning a frequency of the gain element.

3. The device of claim 1, wherein the optical resonator comprises a ring resonator.

4. The device of claim 1, wherein the gain element comprises one or more of a Fabry-Perot laser, a multimodal laser, or a multimodal Fabry-Perot laser.

5. The device of claim 1, wherein one or more of the waveguide or the optical resonator comprises a dielectric material disposed on the silicon material, and wherein the dielectric material comprises silicon nitride.

6. The device of claim 1, wherein the second portion comprises one or more of a chip, an integrated circuit, or a monolithically integrated portion.

7. The device of claim 1, wherein the first tuning element comprises a heating element disposed on at least a portion of the optical resonator.

8. The device of claim 1, further comprising a second tuning element disposed adjacent a portion of the waveguide between the gain element and the optical resonator, wherein the second tuning element is configured to adjust at least a phase of light passing between the gain element and the optical resonator.

9. The device of claim 1, wherein a resonant frequency of a laser cavity of the gain element is adjusted by a laser pumping current.

10. The device of claim 1, wherein the waveguide is optically coupled to the gain element and the optical resonator.

11. The device of claim 1, further comprising an additional gain element, wherein the waveguide comprises:
a first path optically coupled to the gain element;
a second path optically coupled to the additional gain element; and
a combiner configured to combine the first path and the second path into a third path, wherein the optical resonator reflects light back to one or more of the gain element or the additional gain element via the third path.

12. The device of claim 11, wherein the additional gain element is disposed on the first portion.

13. The device of claim 11, further comprising a third tuning element disposed adjacent a portion of the second path of the waveguide between the gain element and the optical resonator, wherein the third tuning element is configured to adjust at least a phase of light passing between the additional gain element and the optical resonator.

14. The device of claim 1, wherein the gain element comprises a multi-spatial-mode laser, and wherein the device further comprises a spatial mode converter configured to convert between a fundamental mode of a broad area input waveguide from the gain element into a fundamental mode of the waveguide, wherein the optical resonator is configured to reflect back light having the fundamental mode of the waveguide.

15. The device of claim 14, wherein the spatial mode converter is disposed on the second portion.

16. The device of claim 1, wherein the first portion comprises a laser cavity and the second portion comprises an external cavity.

17. A method, comprising:
outputting light from a gain element disposed on a first portion to a waveguide disposed on a second portion, wherein the second portion comprises a silicon-based material, and wherein the second portion comprises the waveguide and a partially reflecting optical resonator;
tuning a resonant frequency of the optical resonator with a first tuning element;
providing at least a portion of the light to the partially reflecting optical resonator; and
reflecting at least a portion of the light received by the optical resonator to the gain element via the waveguide.

18. The method of claim 17, wherein the optical resonator is tuned by the first tuning element to cause one or more of: (1) output of a single longitudinal mode by the gain element, (2) output of a single transversal mode by the gain element, (3) narrowing of a linewidth of a lasing mode of the gain element, or (4) tuning a frequency of the gain element.

19. The method of claim 17, wherein the optical resonator is tuned by the first tuning element to cause one or more of injection locking, self-injection locking, or injection pulling of the gain element.

20. The method of claim 17, wherein second portion comprises one or more of a chip, an integrated circuit, or a monolithically integrated portion.
